(19) United States
(12) Patent Application Publication
(10) Pub. No.: US 2019/0206810 A1
(43) Pub. Date: Jul. 4, 2019

(54) POWER SEMICONDUCTOR MODULE, SNUBBER CIRCUIT, AND INDUCTION HEATING POWER SUPPLY APPARATUS

(71) Applicant: NETUREN CO., LTD., Tokyo (JP)

(72) Inventors: Takahiko KANAI, Tokyo (JP); Masato SUGIMOTO, Tokyo (JP); Haruki YOSHIDA, Tokyo (JP)

(73) Assignee: NETUREN CO., LTD., Tokyo (JP)

(21) Appl. No.: 16/325,964

(22) PCT Filed: Aug. 16, 2017
(86) PCT No.: PCT/JP2017/029470

§ 371 Date: Feb. 15, 2019

(30) Foreign Application Priority Data
Aug. 22, 2016 (JP) 2016-161885
Sep. 28, 2016 (JP) 2016-190345

(51) Int. Cl. H01L 23/60; H01L 23/34; H05K 7/14; H01L 25/16; H02M 1/34; H05B 6/04; H05B 6/06; H02M 7/48

(52) U.S. Cl. CPC H01L 23/60; H01L 23/345; H05K 7/1432; H02M 7/48; H02M 1/34; H05B 6/04; H05B 6/06; H01L 25/162

(57) ABSTRACT

A power semiconductor module, a snubber circuit for the power semiconductor module, and induction heating power supply apparatus having the power semiconductor module are provided. The power semiconductor module includes a power semiconductor device configured to perform a switching operation, a casing inside which the power semiconductor device is provided, a control circuit board provided on top of an upper surface of the casing, a control terminal for the power semiconductor device being provided on the upper surface of the casing and connected to the control circuit board, and a shield plate disposed between the control circuit board and the upper surface of the casing to cover the upper surface of the casing and to cover at least one side surface of the casing.

### TECHNICAL FIELD

The present invention relates to a power semiconductor module, a snubber circuit for the power semiconductor module, and an induction heating power supply apparatus.

### BACKGROUND ART

Induction heating has been used as a work heating method in heat treatment of a steel work. In the induction heating, AC power is supplied to a heating coil and a work is heated by an induced current induced by the work placed in a magnetic field formed by the heating coil.

A power supply apparatus for supplying AC power to a heating coil generally converts AC power of a commercial power supply into DC power by a converter, smooths a pulsating current of the DC power by a capacitor, converts the smoothed DC power into AC power by an inverter, and generates high frequency AC power to be supplied to the heating coil (see, e.g., JP 2009-277577A).

The inverter is generally configured as a full bridge circuit having a plurality of arms that are connected in parallel, each arm having two power semiconductor devices capable of performing switching operations and connected in series. The inverter generates high frequency AC power by high speed switching operation of the power semiconductor devices. Typically, each of the arms forming the bridge circuit is individually configured as a module.

A pair of positive and negative DC input terminals electrically connected to an arm are adjacently provided on an upper surface of a power semiconductor module (an upper surface of a casing inside which power semiconductor devices are provided) according to a relevant technique, and output terminals are also provided on the upper surface of the module (see, e.g., JPH8-33346A). In a power semiconductor module according to another relevant technique, a pair of DC input terminals are adjacently provided on one side surface of the module (one side surface of a casing), and output terminals are provided on an opposite side surface of the module (an opposite side surface of the casing) (see, e.g., JP 2004-135444A).

In the power semiconductor module in which the input and output terminals are provided on the side surfaces of the casing, an upper surface of the casing is not closed by wiring members of bus bars etc. connected to the input and output terminals. For this reason, a control circuit board in which a control circuit for controlling switching operation of power semiconductor devices is mounted may be provided top of the upper surface of the casing so that control terminals electrically connected to the power semiconductor devices can be directly connected to the control circuit board (see, e.g., JP 2006-100327A).

High speed switching operation of each of the power semiconductor devices abruptly changes a voltage applied to the power semiconductor device and a current flowing into the power semiconductor device. Due to the abrupt change of the voltage and the current, noise occurs in the periphery of the power semiconductor device. When the noise appears on the control circuit mounted in the control circuit board or control lines extending from the control circuit board, there is a fear that the switching operation of the power semiconductor device may be impeded.

In the case where the control circuit board is provided on top of the upper surface of the casing, the control lines can be shortened. Accordingly, a possibility that the noise may appear on the control lines can be reduced. On the other hand, the control circuit disposed in the vicinity of the power semiconductor device is exposed to the noise easily. Therefore, in the power semiconductor module according to JP 2006-100327A, a shield plate is disposed between the upper surface of the casing and the control circuit board.

Here, the noise includes electrostatic induction noise traveling through stray electrostatic capacitance between adjacent conductors, and electromagnetic induction noise induced by electromagnetic induction between the adjacent inductors. The shield plate which is disposed between the upper surface of the casing and the control circuit board so as to cover the upper surface of the casing is grounded so as to be able to exert a relatively high shielding effect against the electrostatic induction noise. However, magnetic fluxes generating electromagnetic induction can go around so that there is a fear that a satisfactory shielding effect against the electromagnetic induction noise cannot be obtained by the shield plate only covering the upper surface of the casing.

A current change di/dt caused by high speed switching operation of the power semiconductor device generates a surge voltage L×di/dt between opposite ends of the power semiconductor device due to parasitic inductance L of an electric conduction path between the power semiconductor device and a voltage source. There is a fear that an excessive surge voltage may damage the power semiconductor device. In order to protect the power semiconductor device, a snubber circuit for absorbing the surge voltage may be added to the power semiconductor module (see, e.g., JPH8-33346A).

The snubber circuit for the power semiconductor module according to JPH8-33346A is a simple package snubber which is connected between the pair of positive and negative DC input terminals and which is provided as a package for the two power semiconductor devices contained in the power semiconductor module. In the snubber circuit, a capacitor and portions of a pair of terminals connected to the capacitor are molded by a resin to be formed into a module, and the pair of terminals are directly connected to the pair of positive and negative DC input terminals provided adjacently on the upper surface of the power semiconductor module. Besides the simple package snubber, individual snubbers which are connected between the DC input terminals and the output terminals of the power semiconductor module and provided for the power semiconductor devices respectively may be used as the snubber circuit.

In a power semiconductor module in which a pair of positive and negative DC input terminals are adjacently provided on one side surface of the module and output terminals are provided on an opposite side surface of the module, an existing snubber module in which an electronic component such as a capacitor and portions of terminals are molded by a resin cannot be directly connected to the DC input terminals and the output terminals due to an interval between the terminals. The existing snubber module is not suitable for being used as this type of individual snubbers for the power semiconductor module.

In addition, in a snubber circuit, a constant of an electronic component such as a capacitor can be selected in accordance with switching frequency etc. of each power semiconductor device. However, it is effectively impossible to change an electronic component of an existing snubber module in which the electronic component is molded by a resin. Therefore, the snubber module in which the electronic component is molded by the resin has to be designed and manufactured whenever there is a change in design of an inverter such as a change in the switching frequency of the power semiconductor device. When a mold for molding the existing snubber module is used as it is, the degree of freedom for design is limited. When a new mold is manufactured, the cost for manufacturing the mold increases.

In addition, in the snubber module in which the electronic component is molded by the resin, there is a fear that dissipation of heat generated by the electronic component may be impeded. Therefore, deterioration of the electronic component due to the heat becomes an issue.

### SUMMARY

Illustrative aspects of the present invention provide a power semiconductor module and an induction heating power supply apparatus in which shielding for a control circuit can be enhanced to improve operation stability.

According to an illustrative aspect of the present invention, a power semiconductor module includes a power semiconductor device configured to perform a switching operation, a casing inside which the power semiconductor device is provided, a control circuit board provided on top of an upper surface of the casing, a control terminal for the power semiconductor device being provided on the upper surface of the casing and connected to the control circuit board, and a shield plate disposed between the control circuit board and the upper surface of the casing to cover the upper surface of the casing and to cover at least one side surface of the casing.

Illustrative aspects of the present invention also provide a snubber circuit which can be suitably used for a power semiconductor module having a pair of positive and negative DC input terminals provided on a first side surface, and output terminals provided on a second side surface on a side opposite to the first side surface and which is excellent in general-purpose properties and durability, and to provide a power semiconductor module and an induction heating power supply apparatus in which the snubber circuit is used to enhance protection of power semiconductor devices.

According to an illustrative aspect of the present invention,

According to an illustrative aspect of the present invention,

According to an illustrative aspect of the present invention,

### BRIEF DESCRIPTION OF DRAWINGS

FIG. 1 is a circuit diagram illustrating an example of an induction heating power supply apparatus according to an embodiment of the invention.

FIG. 2 is a perspective view of an example of a power semiconductor module provided in an inverter of the induction heating power supply apparatus of FIG. 1.

FIG. 3 is an exploded perspective view of the power semiconductor module of FIG. 2.

FIG. 4 is a circuit diagram illustrating an example of an induction heating power supply apparatus according to another embodiment of the invention.

FIG. 5 is a perspective view of an example of a power semiconductor module provided in an inverter of the induction heating power supply apparatus of FIG. 4.

FIG. 6 is a sectional view of an example of a snubber circuit of the power semiconductor module of FIG. 5.

FIG. 7 is a sectional view of another example of the snubber circuit.

FIG. 8 is a sectional view of another example of the snubber circuit.

FIG. 9 is a sectional view of another example of the snubber circuit.

### DESCRIPTION OF EMBODIMENTS

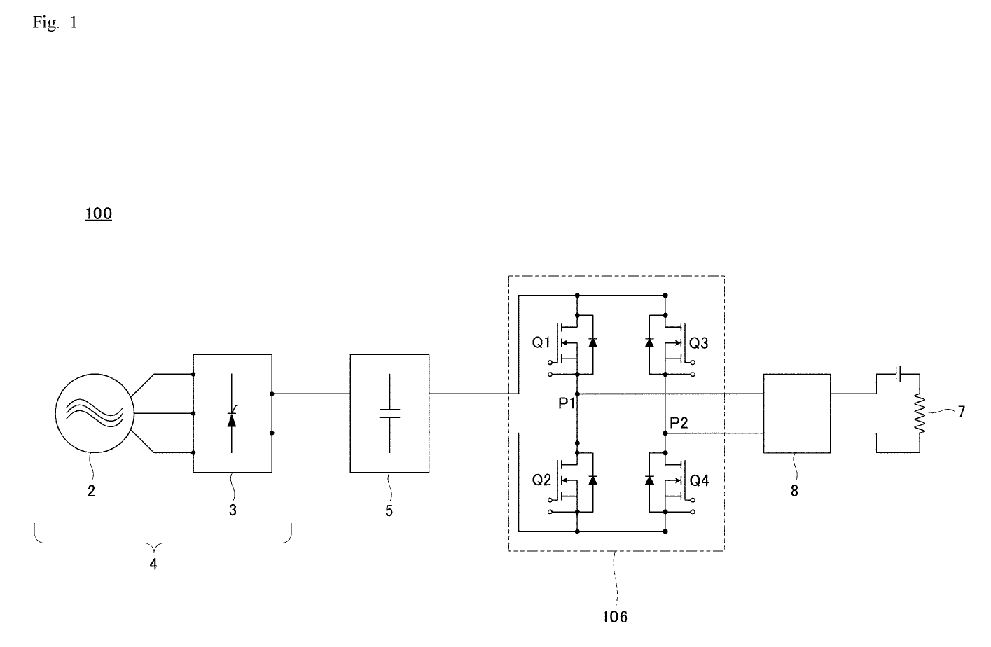

FIG. 1 illustrates an induction heating power supply apparatus 100 according to an embodiment of the invention.

The induction heating power supply apparatus 100 has a DC power supply section 4, a smoothing section 5, and inverter 106. The DC power supply section 4 includes a converter portion 3 which converts AC power supplied from a commercial AC power supply 2 into DC power. The smoothing section 5 smooths a pulsating current of the DC power outputted from the DC power supply section 4. The inverter 106 converts the DC power smoothed by the smoothing section 5 into high frequency AC power.

The inverter 106 is configured as a full bridge circuit including a first arm and a second arm. The first arm includes two power semiconductor devices Q1, Q2 connected in series. The second arm includes two power semiconductor devices Q3, Q4 connected in series. The first arm and the second arm are connected to the smoothing section 5 and in parallel. In the full bridge circuit, a series connection point P1 between the power semiconductor devices Q1, Q2 in the first arm and a series connection point P2 between the power semiconductor devices Q3, Q4 in the second arm are used as output ends. A heating coil 7 is connected between the series connection points P1, P2 through a transformer 8. Freewheeling diodes are connected in antiparallel with the power semiconductor devices respectively.

For example, various power semiconductor devices which can perform switching operation, such as an insulated gate bipolar transistor) (IGBT) and a metal-oxide-semiconductor field-effect transistor (MOSFET) can be used as each of the power semiconductor devices. For example, a material using silicon (Si) and a material using silicon carbide (SiC) may be used as the semiconductor material.

In each of the first arm and the second arm, a side connected to a positive side of the smoothing section 5 is set as a high side, and a side connected to a negative side of the smoothing section 5 is set as a low side. The power semiconductor device Q1 on the high side of the first arm and the power semiconductor device Q4 on the low side of the second arm are turned on and off synchronously. The power semiconductor device Q2 on the low side of the first arm and the power semiconductor device Q3 on the high side of the second arm are turned on and off synchronously. When the power semiconductor devices Q1 and Q4 and the power semiconductor devices Q2, Q3 are turned on alternately, high frequency power is supplied to the heating coil 7.

The power semiconductor devices Q1, Q2 of the first arm and the freewheeling diodes for the power semiconductor devices Q1, Q2 are sealed with a mold resin to be formed into a module. The power semiconductor devices Q3, Q4 of the second arm and the freewheeling diodes for the power semiconductor devices Q3, Q4 are also sealed with a mold resin to be formed into a module.

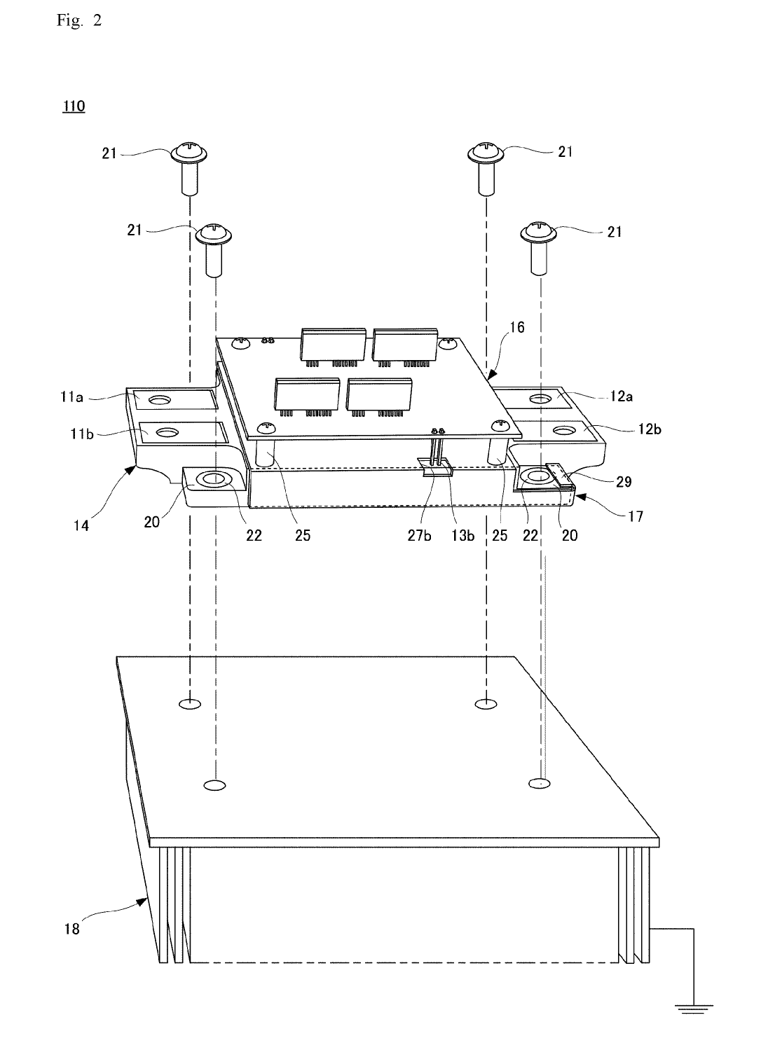

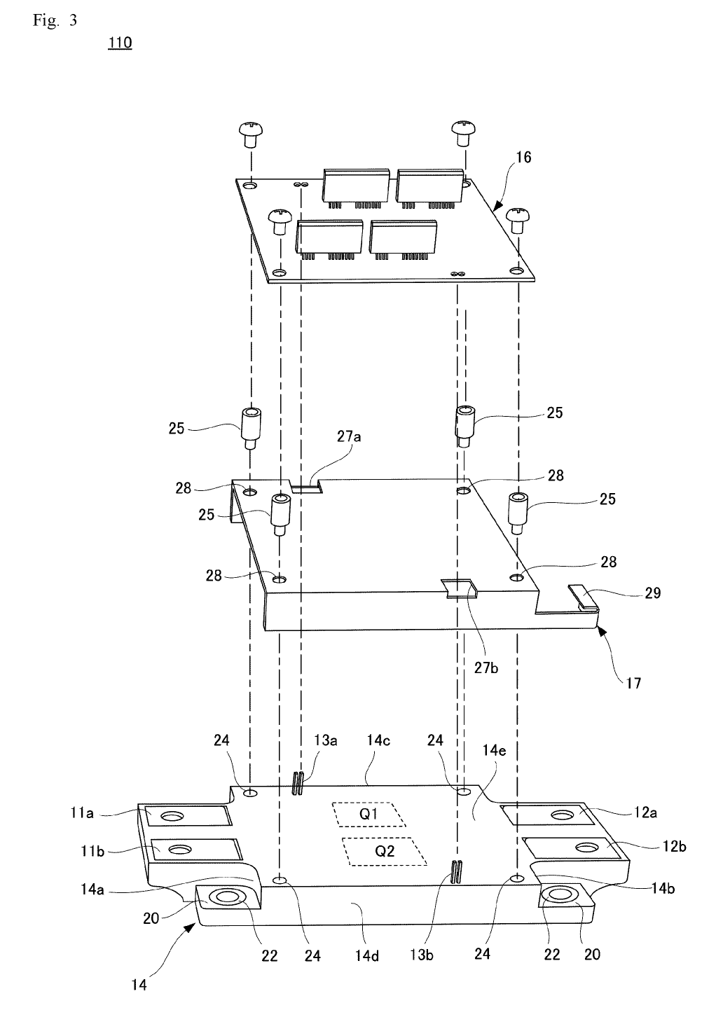

The power semiconductor module including the power semiconductor devices Q1, Q2 of the first arm, and the power semiconductor module including the power semiconductor devices Q3, Q4 of the second arm have the same configuration. The power semiconductor module including the power semiconductor devices Q1, Q2 of the first arm will be described below with reference to FIG. 2 and FIG. 3.

FIG. 2 and FIG. 3 show a configuration example of a power semiconductor module 110.

The power semiconductor module 110 has a pair of a positive-side DC input terminal 11a and a negative-side DC input terminal 11b, output terminals 12a, 12b, and control terminals 13a, 13b, as external connection terminals. The external connection terminals are provided to be exposed to the outside of a casing 14. The casing 14 is made of a mold resin with which the power semiconductor devices Q1, Q2 and the freewheeling diodes for the power semiconductor devices Q1, Q2 are sealed.

The positive-side DC input terminal 11a and the negative-side DC input terminal 11b are provided on a first side surface 14a of the casing 14. The casing 14 is formed substantially into the shape of a rectangular parallelepiped. The positive-side DC input terminal 11a is electrically connected to a power semiconductor device Q1 side end of the first arm including the power semiconductor devices Q1, Q2. The negative-side DC input terminal 11b is electrically connected to a power semiconductor device Q2 side end of the first arm. The positive-side DC input terminal 11a is connected to the positive side of the smoothing section 5 using a wiring member made of a bus bar etc. The negative-side DC input terminal 11b is connected to the negative side of the smoothing section 5 using a wiring member made of a bus bar etc.

The output terminals 12a, 12b are provided on a second side surface 14b of the casing 14 on a side opposite to the first side surface 14a. Both the output terminals 12a, 12b are electrically connected to the series connection point P1 (see FIG. 1) between the power semiconductor devices Q1, Q2 which is an output end of the first arm. The output terminals 12a, 12b may be combined into one. The output terminals 12a, 12b are connected to one end of the heating coil 7 using a wiring member made of a bus bar etc.

The control terminals 13a, 13b are provided on an upper surface 14e of the casing 14. The control terminal 13a is electrically connected to a gate of the power semiconductor device Q1. The control terminal 13b is electrically connected to a gate of the power semiconductor device Q2. In the illustrated example, the control terminal 13a is disposed on an edge portion of the upper surface 14e to which a third side surface 14c of the casing 14 is connected, and the control terminal 13b is disposed on an edge portion of the upper surface 14e to which a fourth side surface 14d of the casing 14 is connected.

A heatsink 18 is disposed on a lower surface side of the casing 14. Casing fixation portions 20 fixed to the heatsink 18 are provided on the first side surface 14a and the second side surface 14b of the casing 14. Insertion holes are formed in the casing fixation portions 20 so that screws 21, examples of fasteners for fixing the casing fixation portions 20 to the heatsink, can be inserted through the insertion holes. Ring-like washers 22 are fitted into the insertion holes. The casing fixation portions 20 are fixed to the heatsink 18 by the screws 21 respectively. The heatsink 18 is tightly in contact with the lower surface of the casing 14.

Heat generated by the power semiconductor devices Q1, Q2 and the freewheeling diodes for the power semiconductor devices Q1, Q2 provided inside the casing 14 is transferred to the heatsink 18 through the mold resin forming the casing 14. Then, the heat is dissipated by the heatsink 18. The heatsink 18 is grounded through a housing frame etc. of the induction heating power supply apparatus 100 supporting the heatsink 18 from the viewpoints of noise resistance and safety.

The power semiconductor module 110 further has a control circuit board 16 and a shield plate 17.

A control circuit for controlling switching operation of the power semiconductor devices Q1, Q2 is mounted in the control circuit board 16. Threaded holes 24 serving as attachment portions to which the control circuit board 16 is attached are provided respectively at four corners of the upper surface 14e of the casing 14. Spacers 25 serving as fittings for attaching the control circuit board 16 are screwed into the threaded holes 24. The control circuit board 16 is supported on the spacers 25 so as to be provided on top of the upper surface 14e with a gap formed between the control circuit board 16 and the upper surface 14e. The control circuit board 16 is screwed to the spacers 25 to be attached to the casing 14.

The control terminals 13a, 13b provided on the upper surface 14e of the casing 14 are soldered to the control circuit board 16 respectively via through holes in the control circuit board 16 provided over the upper surface 14e.

The shield plate 17 is made of a conductor such as metal. The shield plate 17 is disposed between the upper surface 14e of the casing 14 and the control circuit board 16 provided above the upper surface 14e. Thus, the shield plate 17 covers the upper surface 14e. Further, the shield plate 17 covers the third side surface 14c and the fourth side surface 14d. The third side surface 14c is connected to the edge portion of the upper surface 14e on which the control terminal 13a is provided. The fourth side surface 14d is connected to the edge portion of the upper surface 14e on which the control terminal 13b is provided. The control terminals 13a, 13b are exposed respectively through windows 27a and 27b formed at appropriate places of the shield plate 17.

The shield plate 17 is fixed to the casing 14 by the spacers 25 serving as the fittings for attaching the control circuit board 16. Through holes 28 overlapping with the threaded holes 24 at the four corners of the upper surface 14e of the casing 14 respectively are formed in the shield plate 17. The spacers 25 are screwed into the threaded holes 24 through the through holes 28. Edge portions of the shield plate 17 enclosing the through holes 28 are interposed between the edge portions of the upper surface 14e enclosing the threaded holes 24 and the spacers 25. Thus, the shield plate 17 is fixed to the casing 14.

The shield plate 17 shields the control circuit mounted in the control circuit board 16 and control lines extending from the control circuit board 16, from noise generated in the circumferences of the power semiconductor devices Q1, Q2 provided inside the casing 14. The control lines mean the control terminals 13a, 13b directly connected to the control circuit board 16.

The control circuit board 16 is provided on top of the upper surface 14e of the casing 14. The control terminals 13a, 13b are also provided on the upper surface 14e. The shield plate 17 covering the upper surface 14e is interposed between the power semiconductor devices Q1, Q2 and the control circuit board 16 with the control terminals 13a, 13b. Therefore, electrostatic induction noise occurring in the circumferences of the power semiconductor devices Q1, Q2 flows into the shield plate 17 through stray electrostatic capacitance between the power semiconductor devices Q1, Q2 and the shield plate 17.

From the viewpoint of enhancement of a shielding effect of the shield plate 17 against the electrostatic induction noise, it is preferable that the shield plate 17 is grounded. In the example, the heatsink 18 tightly contacting the lower surface of the casing 14 is grounded, and the shield plate 17 is grounded through the heatsink 18. A shield plate fixation portion 29 is provided in the shield plate 17. The shield plate fixation portion 29 is superimposed on a corresponding one of the casing fixation portions 20 of the casing 14 fixed to the heatsink 18. The shield plate fixation portion 29 is interposed between the corresponding casing fixation portion 20 and a corresponding one of the screws 21 fixing the corresponding casing fixation portions 20 to the heatsink 18. The washers 22 are fitted into the insertion holes of the casing fixation portions 20 through which the screws 21 are inserted. The shield plate fixation portion 29 is electrically connected to the heatsink 18 through a corresponding one of the washers 22 and the corresponding screw 21. Thus, the shield plate 17 is grounded through the heatsink 18. Due to the shield plate 17 which is grounded, the control circuit mounted in the control circuit board 16 and the control terminals 13a, 13b serving as the control lines are shielded from the electrostatic induction noise.

Further, by the shield plate 17, the control circuit mounted in the control circuit board 16 and the control terminals 13a, 13b serving as the control lines are also shielded from electromagnetic induction noise generated in the circumferences of the power semiconductor devices Q1, Q2 provided inside the casing 14.

Magnetic fluxes generating electromagnetic induction are radiated not only from the upper surface 14e of the casing 14 but also from the side surfaces of the casing 14. The magnetic fluxes radiated from the side surfaces are arranged to go around. As a result, the magnetic fluxes are interlinked with the control circuit and the control terminals 13a, 13b to thereby generate electromagnetic induction. Against the magnetic fluxes radiated from the side surfaces of the casing 14 and going around thus, the shield plate 17 covers not only the upper surface 14e of the casing 14 but also the third side surface 14c and the fourth side surface 14d. The magnetic fluxes radiated from the third side surface 14c and the fourth side surface 14d in addition to the magnetic flux radiated from the upper surface 14e are blocked by the shield plate 17. Thus, electromagnetic induction noise induced by the control circuit and the control terminals 13a, 13b can be reduced.

Particularly, in the example, the control terminals 13a, 13b are provided on the edge portions of the upper surface 14e of the casing 14, and the third side surface 14c and the fourth side surface 14d of the casing 14 connected to the edge portions are covered with the shield plate 17. Accordingly, the electromagnetic induction noise induced by the control terminals 13a, 13b can be reduced effectively.

The plate thickness of the shield plate 17 can be set based on a permeation depth of an eddy current flowing into the shield plate 17 due to electromagnetic induction. An eddy current flowing into a conductor placed in an alternating field is converted into heat due to electric resistance of the conductor. Energy of the alternating field is converted into heat and consumed by the shield plate 17 to thereby produce the shielding effect of the shield plate 17 against electromagnetic induction noise. A major part of the eddy current flows into a front surface of the conductor due to a skin effect. The permeation depth means a depth from the front surface, at which a current density decreases to be 0.37 times as high as that in the front surface. The permeation depth can be expressed by the following expression.

δ=503√(ρ/μf)

wherein δ: the permeation depth (m), ρ: volume resistivity of the conductor (×10⁻⁸ Ωm), μ: relative permeability of the conductor, f: frequency (Hz)

For example, assume that the shield plate 17 is made of copper (volume resistivity ρ=1.55, relative permeability μ=1), and the frequency f of switching operation of each of the power semiconductor devices Q1, Q2 is 200 kHz. In this case, the permeation depth δ is equal to 0.14 mm based on the aforementioned expression. It has been known that magnetic field intensity is attenuated by 26 db (95%) at a plate thickness three times as large as the permeation depth δ. Therefore, the plate thickness of the shield plate 17 can be set at 0.42 mm to 0.70 mm, which is three to five times as large as the permeation depth δ.

In this manner, not only the upper surface 14e of the casing 14 on top of which the control circuit board 16 is put and on which the control terminals 13a, 13b are provided, but also at least some of the side surfaces of the casing 14 are covered with the shield plate 17. Accordingly, the shielding for the control circuit and the control terminals 13a, 13b serving as the control lines can be enhanced so that stability of the power semiconductor module 110 and the induction heating power supply apparatus 100 can be improved.

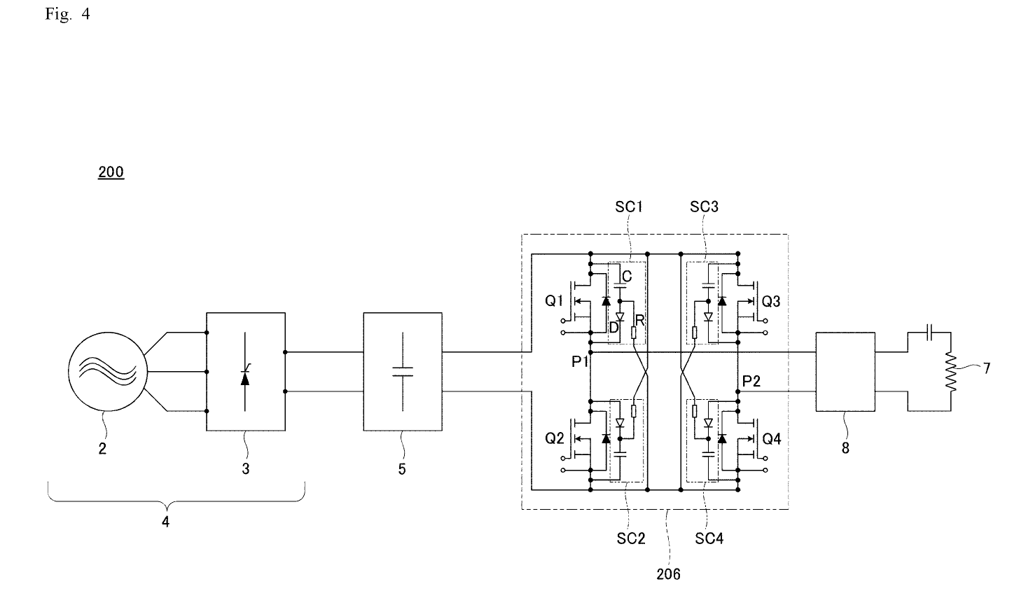

FIG. 4 shows an induction heating power supply apparatus 200 according to another embodiment of the invention. In the following description, similar or identical constituents to those of the induction heating power supply apparatus 100 in FIG. 1 will be referred to by the same signs correspondingly and respectively, and duplicate description thereof will be omitted.

The induction heating power supply apparatus 200 has an inverter 206 that is different from the inverter 106 of the induction heating power supply apparatus 100.

High speed switching operation of each of power semiconductor devices Q1, Q2, Q3, Q4 changes a current flowing into the power semiconductor device Q1, Q2, Q3, Q4 abruptly. Due to parasitic inductance of an electric conduction path between the power semiconductor device Q1, Q2, Q3, Q4 and a smoothing section 5 serving as a voltage source, a surge voltage is generated between opposite ends of the power semiconductor device Q1, Q2, Q3, Q4. In order to absorb the surge voltage, a corresponding snubber circuit SC1, SC2, SC3, SC4 is provided individually for the power semiconductor device Q1, Q2, Q3, Q4 of the inverter 206.

The snubber circuit SC1, SC2, SC3, SC4 is a so-called non-discharge type RCD snubber circuit which is configured to include a resistor R, a capacitor C and a diode D in an example illustrated in FIG. 4.

In the snubber circuit SC1 for the power semiconductor device Q1 on a high side of a first arm, the capacitor C and the diode D are connected in series between the opposite ends of the power semiconductor device Q1 (between a collector and an emitter in the case where the power semiconductor device Q1 is an IGBT or between a drain and a source in the case where the power semiconductor device Q1 is an MOSFET), and the resistor R is connected between a series connection point between the capacitor C and the diode D and a negative side of the smoothing section 5.

In addition, in the snubber circuit SC2 for the power semiconductor device Q2 on a low side of the first arm, the capacitor C and the diode D are connected in series between the opposite ends of the power semiconductor device Q2, and the resistor R is connected between a series connection point between the capacitor C and the diode D and a positive side of the smoothing section 5.

The snubber circuit SC3 for the power semiconductor device Q3 on a high side of a second arm is configured similarly to the snubber circuit SC1. The snubber circuit SC4 for the power semiconductor device Q4 on a low side of the second arm is configured similarly to the snubber circuit SC2.

Each snubber circuits SC1, SC2, SC3, SC4 is not limited to the configuration described above. For example, each snubber circuit SC1, SC2, SC3, SC4 may be a so-called charge-discharge type RCD snubber circuit in which arrangement of the capacitor C and the diode D relative to the power semiconductor device is reverse to that in the illustrated example and the resistor R is connected in parallel with the diode D, or a so-called RC snubber circuit in which the resistor R and the capacitor C are connected in series between the opposite ends of the power semiconductor device.

The power semiconductor devices Q1, Q2 of the first arm and freewheeling diodes for the power semiconductor devices Q1, Q2 are provided inside a casing to be formed into a module. The snubber circuits SC1, SC2 are connected to external connection terminals and disposed outside the casing. The external connection terminals are provided to be exposed to the outside of the casing. The casing inside which the power semiconductor devices Q1, Q2 and the freewheeling diodes for the power semiconductor devices Q1, Q2 are provided may be filled with a mold resin so that the power semiconductor devices Q1, Q2 and the freewheeling diodes for the power semiconductor devices Q1, Q2 can be sealed with the mold resin. Similarly, the power semiconductor devices Q3, Q4 of the second arm and freewheeling diodes for the power semiconductor devices Q3, Q4 are also provided inside a casing to be formed into a module. The snubber circuits SC3, SC4 are connected to external connection terminals and disposed outside the casing. The external connection terminals are provided to be exposed to the outside of the casing.

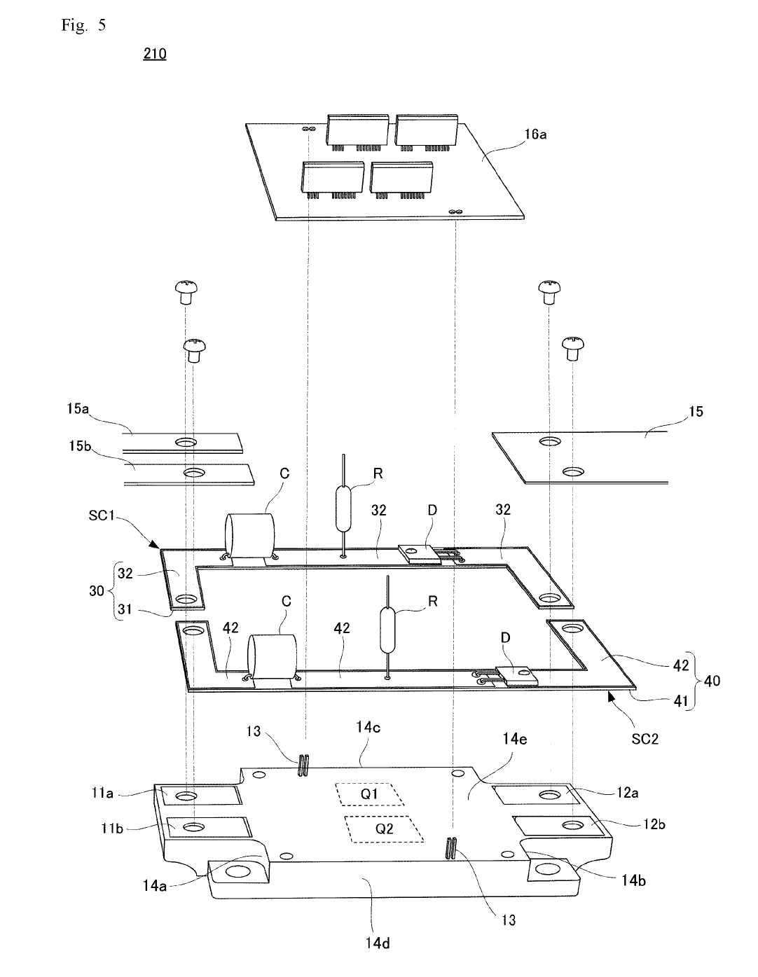

FIG. 5 shows a configuration example of a power semiconductor module 210 including the power semiconductor devices Q1, Q2 of the first arm. In the following description, similar or identical constituents to those of the power semiconductor module 110 in FIG. 3 will be referred to by the same signs correspondingly and respectively, and duplicate description thereof will be omitted.

Similarly to the power semiconductor module 110, the power semiconductor module 210 has input terminals 11a, 11b, output terminals 12a, 12b, and a plurality of control terminals 13.

The input terminals 11a, 11b disposed on a first side surface 14a of the power semiconductor module 210. The positive-side DC input terminal 11a is connected to the positive side of the smoothing section 5 using a wiring member 15a made of a bus bar etc. The negative-side DC input terminal 11b is connected to the negative side of the smoothing section 5 using a wiring member 15b.

The output terminals 12a, 12b are disposed on a second side surface 14b of the power semiconductor module 210 on a side opposite to the first side surface 14a. The output terminals 12a, 12b are connected to a transformer 8 (see FIG. 4) using a wiring member 15.

The plurality of control terminals 13 are disposed on an upper surface 14e of the power semiconductor module 210. While a portion of the control terminals 13 is electrically connected to a gate of the power semiconductor device Q1, the other portion of the control terminals 13 is electrically to a gate of the power semiconductor device Q2. The control terminals 13 are connected to a control circuit 16a which controls switching operation of the power semiconductor devices Q1, Q2. In the example, the control circuit 16a is placed and disposed on the upper surface 14e of the power semiconductor module 210, and the control terminals 13 are soldered to the control circuit 16a through through holes formed in a circuit board of the control circuit 16a.

The snubber circuit SC1 for the power semiconductor device Q1 has the resistor R, the capacitor C and the diode D as described above. In addition, the snubber circuit SC1 further has a circuit board 30 on which the electronic components R, C, D are mounted in an exposed manner. The circuit board 30 has an insulating base 31 and a conductor layer 32.

The insulating base 31 extends along the first side surface 14a of the power semiconductor module 210, the second side surface 14b of the power semiconductor module 210 and a third side surface 14c of the power semiconductor module 210, bridging between the positive-side DC input terminal 11a and the output terminal 12a. A pair of the positive-side and negative-side DC input terminals 11a, 11b are provided on the first side surface 14a. The two output terminals 12a, 12b are provided on the second side surface 14b. The third side surface 14c is disposed between the first side surface 14a and the second side surface 14b.

The conductor layer 32 is provided on an upper surface of the insulating base 31 on which the resistor R, the capacitor C and the diode D are disposed. The conductor layer 32 forms a circuit pattern connected to the positive-side DC input terminal 11a and the output terminal 12a respectively.

The conductor layer 32 is typically formed of a copper foil. For example, various materials such as Bakelite, paper phenol in which paper is solidified with a phenol resin, and glass epoxy in which glass fibers are solidified with an epoxy resin can be used as the insulating base 31. However, a material higher in bending rigidity per unit thickness than copper is preferred. Among the enumerated materials, the glass epoxy is suitable.

Electronic component mounting portions to which the resistor R, the capacitor C and the diode D are attached respectively are provided at appropriate places of the circuit board 30 in accordance with the circuit pattern. Each of the electronic component mounting portions can be formed in accordance with a form of a corresponding electronic component.

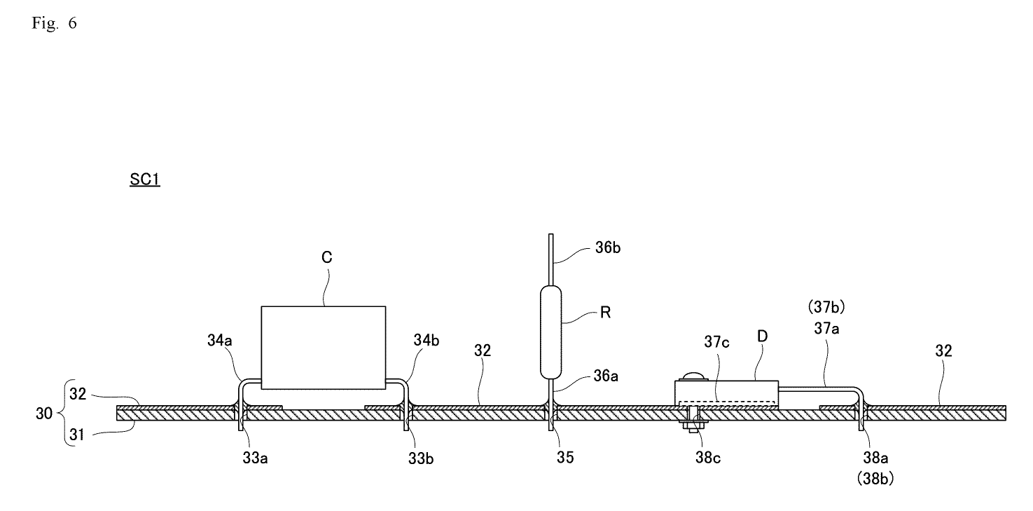

FIG. 6 illustrates the configuration of the snubber circuit SC1.

In an example illustrated in FIG. 6, the capacitor C is a lead-type capacitor. Electronic component mounting portions 33a, 33b corresponding to the capacitor C are formed as through holes. Two leads 34a, 34b of the capacitor C are inserted into the electronic component mounting portions 33a, 33b respectively and soldered to lands made of the conductor layer 32.

The resistor R is also a lead-type resistor. An electronic component mounting portion 35 corresponding to the resistor R is formed as a through hole. One lead 36a of the resistor R is inserted into the electronic component mounting portion 35 and soldered to a land made of the conductor layer 32.

The diode D has pins 37a, 37b and a frame 37c. The pins 37a, 37b are electrically connected to an end of a diode chip sealed with a mold resin. The frame 37c is electrically connected to the other end of the diode chip and exposed in a back surface of the package. Electronic component mounting portions 38a, 38b corresponding to the pins 37a, 37b are formed as through holes. The pins 37a, 37b are inserted into the electronic component mounting portions 38a, 38b respectively and soldered to lands made of the conductor layer 32. In addition, an electronic component mounting portion 38c corresponding to the frame 37c is also formed as a through hole. However, the frame 37c in contact with a land made of the conductor layer 32 is screwed into the electronic component mounting portion 38c.

The configurations of the resistor R, the capacitor C and the diode D and the respective electronic component mounting portions described above are merely examples and may be changed as appropriate. For example, a screw clamp type resistor may be used as the resistor R and a screw clamp type capacitor may be used as the capacitor C. In addition, a full mold package type diode having all electric connection portions provided by pins or a lead-type diode may be used as the diode D. Further, a surface mount type one may be used as the resistor R, the capacitor C or the diode D. In this case, the through holes may be replaced by pads as the electronic component mounting portions of the circuit board 30. Further, in the illustrated example, the resistor R, the capacitor C or the diode D is directly attached to and mounted on the circuit board 30 by soldering or screwing etc. However, the resistor R, the capacitor C or the diode D may be electrically connected to the circuit board 30 or may be mounted on the circuit board 30 through a connection terminal or a wiring material. For example, the resistor R may be mounted on the circuit board 30 as follows. That is, a connection terminal is crimped to the lead 36a of the resistor R, and connection terminals are also crimped to two ends of a wiring material. One of the connection terminals of the wiring material is connected to the connection terminal of the resistor R, and the other connection terminal of the wiring material is screwed into the electronic component mounting portion 35. Thus, the resistor R is mounted on the circuit board 30.

In the snubber circuit SC1 configured as described above, one end portion of the circuit board 30 is jointly fastened together with the wiring member 15a, to the positive-side DC input terminal 11a by a screw, and the other end portion of the circuit board 30 is jointly fastened together with the wiring member 15, to the output terminal 12a by a screw. In addition, a lead 36b of the resistor R is electrically connected to the negative-side DC input terminal 11b and mounted on the power semiconductor module 210.

Refer to FIG. 5 again. The snubber circuit SC2 for the power semiconductor device Q2 has the resistor R, the capacitor C and the diode D as described above. In addition, the snubber circuit SC2 further has a circuit board 40 on which the electronic components R, C, D are mounted.

Similarly to the circuit board 30 of the snubber circuit SC1, the circuit board 40 is has an insulating base 41 and a conductor layer 42. The insulating base 41 extends along the first side surface 14a, the second side surface 14b and a fourth side surface 14d of the power semiconductor module 210, bridging between the negative-side DC input terminal 11b and the output terminal 12b. The fourth side surface 14d is disposed between the first side surface 14a and the second side surface 14b.

The conductor layer 42 is provided on an upper surface of the insulating base 41. The conductor layer 42 forms a circuit pattern which is connected to the negative-side DC input terminal 11b and the output terminal 12b respectively. Electronic component mounting portions to which the resistor R, the capacitor C, and the diode D are attached respectively are provided at appropriate places of the circuit board 40 in accordance with the circuit pattern.

In the snubber circuit SC2 configured as described above, one end portion of the circuit board 40 is jointly fastened together with the wiring member 15b, to the negative-side DC input terminal 11b by a screw, and the other end portion of the circuit board 40 is jointly fastened together with the wiring member 15, to the output terminal 12b by a screw. In addition, one lead of the resistor R is electrically connected to the positive-side DC input terminal 11a and mounted on the power semiconductor module 210.

According to the aforementioned power semiconductor module 210, a surge voltage occurring between opposite ends of the power semiconductor devices Q1, Q2 in accordance with switching operation of the power semiconductor devices Q1, Q2 is absorbed respectively by the snubber circuits SC1, SC2 provided individually for the power semiconductor devices Q1, Q2. Thus, the power semiconductor devices Q1, Q2 can be suppressed from being damaged due to the surge voltage.

The resistor R, the capacitor C and the diode D included in the snubber circuit SC1 are mounted on the circuit board 30 in an exposed manner. The resistor R, the capacitor C and the diode D included in the snubber circuit SC2 are also mounted on the circuit board 40 in an exposed manner. The electronic components R, C, D can be changed easily. Thus, the circuit board 30, 40 can be generalized for design change of the inverter 206 such as change of switching frequency of the power semiconductor device Q1, Q2, and electronic components having appropriate constants can be used as the electronic components R, C, D mounted on the circuit board 30, 40 so as to absorb a surge voltage effectively.

The resistor R, the capacitor C and the diode D are mounted on the circuit board 30, 40 in an exposed manner. Accordingly, the snubber circuit is excellent in dissipation of heat generated by the electronic components R, C, D so that deterioration of the electronic components R, C, D caused by the heat can be suppressed. Thus, durability of the snubber circuit can be enhanced.

Further, wiring inductance is also present in the snubber circuit per se. The circuit board 30 of the snubber circuit SC1 is provided to extend along the first side surface 14a, the third side surface 14c and the second side surface 14b of the power semiconductor module 210. The circuit board 30 is directly connected to the positive-side DC input terminal 11a provided on the first side surface 14a, and the output terminal 12a provided on the second side surface 14b on a side opposite to the first side surface 14a. Thus, the length of an electric conduction path of the snubber circuit SC1 can be made as short as possible. Thus, the inductance of the snubber circuit SC1 can be reduced to suppress a surge voltage, so that noise radiated due to the surge current flowing into the snubber circuit SC1 can be suppressed.

The circuit board 30 of the snubber circuit SC1 is extended along the first side surface 14a, the third side surface 14c and the second side surface 14b of the power semiconductor module 210. Accordingly, the circuit board 30 is shaped like a flat plate having no portion bent in a thickness direction. Thus, the conductor layer 32 can be formed on the insulating base 31 easily.

Similarly, the circuit board 40 of the snubber circuit SC2 is also provided to extend along the first side surface 14a, the fourth side surface 14d and the second side surface 14b of the power semiconductor module 210. The circuit board 40 is directly connected to the negative-side DC input terminal 11b provided on the first side surface 14a, and the output terminal 12b provided on the second side surface 14b on the opposite side on the first side surface 14a. The length of an electric conduction path of the snubber circuit SC2 can be made as short as possible so that the inductance can be reduced. In addition, the circuit board 40 is formed into a flat plate shape so that the conductor layer 42 can be formed on the insulating base 41 easily.

From the viewpoint of reduction of the inductance of the snubber circuit SC1, SC2, the thickness of the conductor layer 32, 42 of the circuit board 30, 40 may be increased, or a conductor layer may be provided on each of opposite upper and lower surfaces of the insulating base 31, 41 of the circuit board 30, 40.

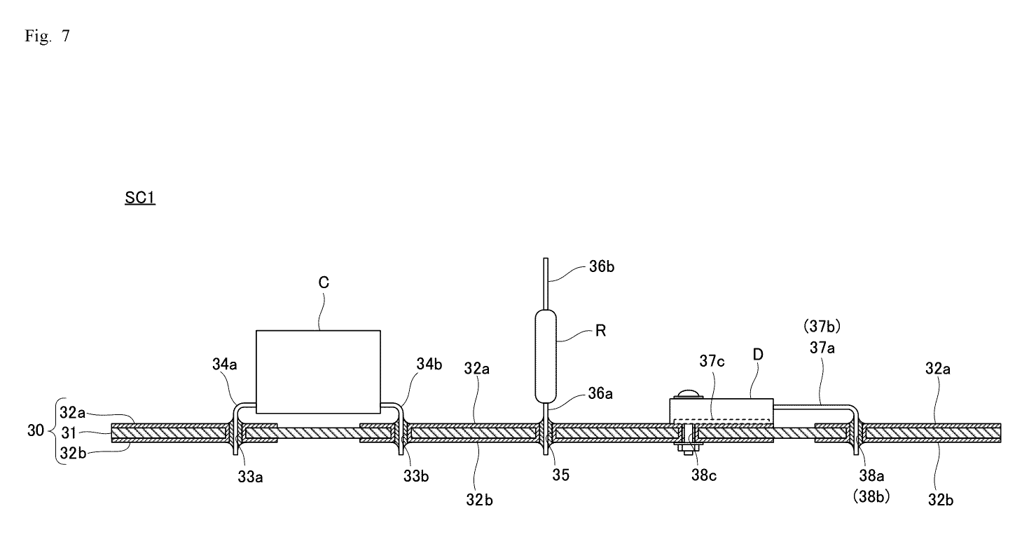

FIG. 7 illustrates another example of the snubber circuit SC1.

In an example shown in FIG. 7, conductor layers 32a, 32b are provided on opposite upper and lower surfaces of an insulating base 31 respectively. Circuit patterns the same as each other are formed in the conductor layer 32a on the upper surface side of the insulating base 31 and the conductor layer 32b on the lower surface side of the insulating base 31. Electronic components such as a capacitor C are disposed on the conductor layer 32a.

The conductor layer 32a on the upper surface side of the insulating base 31 and the conductor layer 32b on the lower surface side of the insulating base 31 are electrically and thermally connected to each other through electronic component mounting portions 33a, 33b, 35, 38a, 38b, 38c which are formed as through holes.

With the provision of the conductor layers 32a, 32b which have the same patterns as each other on the opposite upper and lower surfaces of the insulating base 31 and are electrically connected to each other through the through holes, a sectional area of an electric conduction path of a circuit board 30 can be made larger and inductance of the snubber circuit SC1 can be made smaller than those in the case where a conductor layer 32 is provided only on the upper surface of the insulating base 31. Further, the conductor layers 32a, 32b are also thermally connected to each other through the through holes. Accordingly, an area of heat radiation can be also made larger than that in the case where the conductor layer 32 is provided only on the upper surface of the insulating base 31. Accordingly, dissipation of heat generated by the electronic components such as the capacitor C can be accelerated so that deterioration of the electronic components caused by the heat can be suppressed. Thus, durability of the snubber circuit SC1 can be enhanced more greatly.

From the viewpoint of reduction of the inductance of the snubber circuit SC1, it is preferable that the total thickness of the conductor layer or layers, that is, the thickness of the conductor layer 32 in the case where the conductor layer 32 is provided only on the upper surface of the insulating base 31, or the total thickness of the conductor layers 32a, 32b in the case where the conductor layers 32a, 32b are provided on the opposite upper and lower surfaces of the insulating base 31 is equal to or greater than 0.1 mm. Since the circuit board 30 is formed into a flat plate shape, the conductor layer or layers can be formed easily on the insulating base 31 even when the conductor layer or layers are comparatively thick.

In addition, assume that leads 34a, 34b etc. of the capacitor C are manually soldered to lands made of the conductor layers. In this case, when the total thickness of the conductor layers is excessively large, it takes time to increase the temperature of each of the lands to a solder melting temperature by a soldering iron. Therefore, the total thickness of the conductor layers is preferably smaller than 2.0 mm in consideration of soldering workability.

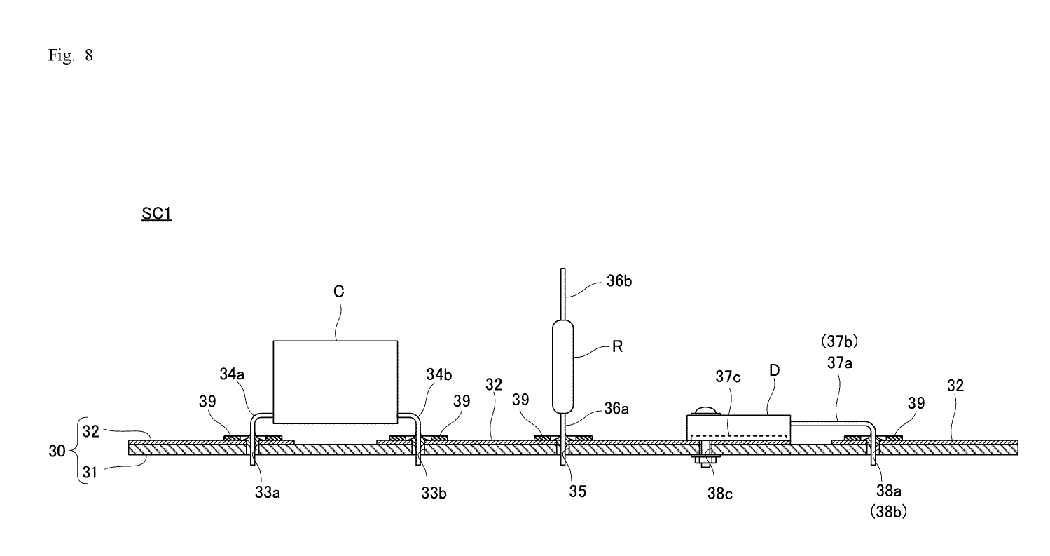

FIG. 8 illustrates another example of the snubber circuit SC1.

In an example shown in FIG. 8, solder resist films 39 are formed on a front surface of a conductor layer 32 and in the circumferences of electronic component mounting portions 33a, 33b, 35, 38a, 38b of a circuit board 30 to which components such as a capacitor C are soldered.

As described above, leads 34a, 34b of the capacitor C are inserted into the electronic component mounting portions 33a, 33b respectively and soldered to lands made of the conductor layer 32. Each of the electronic component mounting portions 33a, 33b is formed as a through hole. The corresponding solder resist films 39 are formed annularly on the front surface of the conductor layer 32 so as to surround the lands to which the leads 34a, 34b are soldered.

Similarly, the corresponding annular solder resist films 39 are formed on the front surface of the conductor layer 32 and also in the periphery of the electronic component mounting portion 35 to which a lead 36a of a resistor R is soldered, and the circumferences of the electronic component mounting portions 38a, 38b to which pins 37a, 37b of a diode D are soldered.

In this manner, the solder resist films 39 are formed in advance on the front surface of the conductor layer 32 and in the circumferences of the electronic component mounting portions 33a, 33b, 35, 38a, 38b to which the components are soldered. Accordingly, heat can be suppressed from being radiated from the front surface of the conductor layer 32 in the circumferences of the electronic component mounting portions. Thus, even when the thickness of the conductor layer 32 is increased, temperature of the land for each of the electronic component mounting portions 33a, 33b, 35, 38a, 38b can be increased efficiently by a solder iron so that efficiency of manual soldering work can be improved.

The conductor layer 32 is provided only on the upper surface of the insulating base 31 in the example shown in FIG. 8. However, when conductor layers 32a, 32b are provided on opposite upper and lower surfaces of the insulating base 31 as shown in FIG. 7, solder resist films 39 may be formed on each of a front surface of the conductor layers 32a on the upper surface side of the insulating base 31 and a front surface of the conductor layer 32b on the lower surface side of the insulating base 31 and in the circumferences of the electronic component mounting portions 33a, 33b, 35, 38a, 38b.

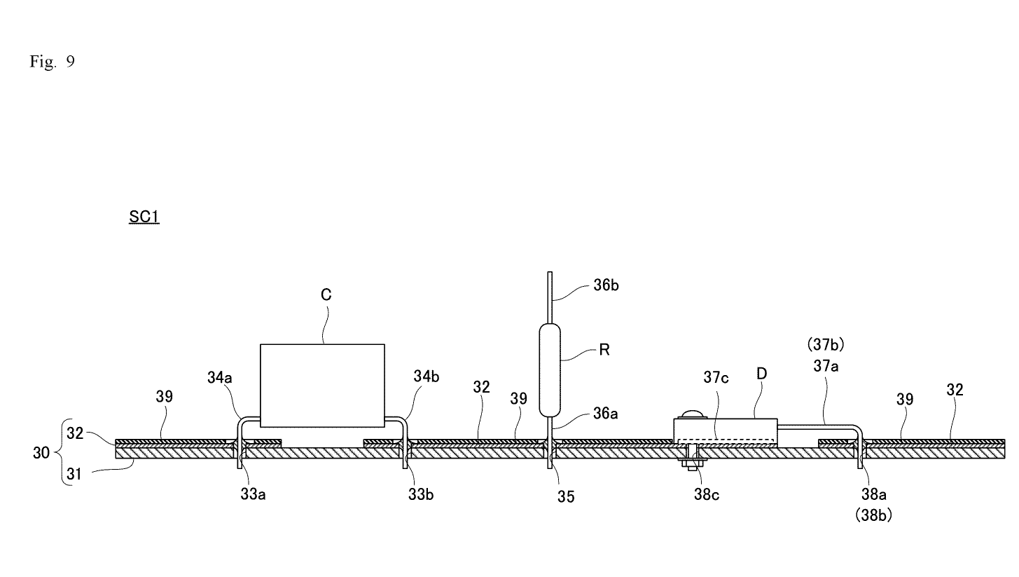

FIG. 9 illustrates another example of the snubber circuit SC1.

In an example shown in FIG. 9, a solder resist film 39 is formed all over a front surface of a conductor layer 32 other than electronic component mounting portions 33a, 33b, 35, 38a, 38b, 38c of a circuit board 30 to which electronic components such as a capacitor C are attached. In this case, the circuit board 30 on which components to be soldered such as the capacitor C are mounted can be soaked in a solder tank in place of manual soldering and the components can be collectively soldered. Thus, productivity of the snubber circuit SC1 can be improved.

This application is based on Japanese Patent Application No. 2016-161885 filed on Aug. 22, 2016 and Japanese Patent Application No. 2016-190345 filed on Sep. 28, 2016, the entire contents of which are incorporated herein by reference.

1. A power semiconductor module comprising:
a power semiconductor device configured to perform a switching operation;
a casing inside which the power semiconductor device is provided;
a control circuit board provided on top of an upper surface of the casing, a control terminal for the power semiconductor device being provided on the upper surface of the casing and connected to the control circuit board; and
a shield plate disposed between the control circuit board and the upper surface of the casing to cover the upper surface of the casing and to cover at least one side surface of the casing.

2. The power semiconductor module according to claim 1, wherein the control terminal is provided on an edge portion of the upper surface of the casing, and
wherein the shield plate covers the at least one side surface of the casing that is connected to the edge portion of the upper surface of the casing.

3. The power semiconductor module according to claim 1, wherein the shield plate has a shield plate fixation portion configured to be fixed to the casing such that, when the shield plate fixation portion is fixed to the casing, the shield plate is grounded.

4. The power semiconductor module according to claim 3, further comprising a heatsink tightly contacting a lower surface of the casing and grounded,
wherein the shield plate fixation portion is electrically connected to the heatsink when the shield plate fixation portion is fixed to the casing.

5. The power semiconductor module according to claim 4, wherein the casing has a casing fixation portion configured to be fixed to the heatsink, and
wherein the shield plate fixation portion is provided on top of the casing fixation portion such that the shield plate fixation portion is electrically connected to the heatsink through at least one of the casing fixation portion and a fastener that fixes the casing fixation portion to the heatsink.

6. An induction heating power supply apparatus comprising an inverter configured to convert DC power into AC power
wherein the inverter is configured as a bridge circuit including a plurality of interconnected power semiconductor modules according to claim 1.

7. A snubber circuit for a power semiconductor module, the power semiconductor module having an arm including two power semiconductor devices that are capable of performing switching operations and are connected in series,
wherein the power semiconductor module has a pair of positive-side and negative-side DC input terminals and output terminals that are electrically connected to the arm, the pair of positive-side and negative-side DC input terminals are provided on a first side surface of the power semiconductor module, and the output terminals are provided on a second side surface of the power semiconductor module on a side opposite to the first side surface,
wherein the snubber circuit comprises:
a circuit board having an insulating base and a conductor layer, the insulating base extending along a side surface of the power semiconductor module and bridging between a corresponding one of the DC input terminals and a corresponding one of the output terminals, the conductor layer being provided on at least one of an upper surface and a lower surface of the insulating base and forming a circuit pattern connected to the corresponding DC input terminal and the corresponding output terminal respectively; and
an electric component mounted on the circuit board in an exposed manner.

8. The snubber circuit according to claim 7, wherein the conductor layer is provided on each of the upper surface and the lower surface of the insulating base, and each of the conductor layer on the upper surface side of the insulating base and the conductor layer on the lower surface side of the insulating base forming the same circuit pattern, and
wherein an electronic component mounting portion of the circuit board is configured as a through hole such that the conductor layer on the upper surface side of the insulating base and the conductor layer on the lower surface side of the insulating base are electrically and thermally connected to each other via the through hole.

9. The snubber circuit according to claim 7, wherein a total thickness of the conductor layer is equal to or greater than 0.1 mm but smaller than 2.0 mm.

10. The snubber circuit according to claim 7, wherein the electronic component includes a soldered component, and
wherein a solder resist film is formed on a front surface of the conductor layer and in a periphery of the electronic component mounting portion of the circuit board where the soldered component is soldered.

11. The snubber circuit according to claim 10, wherein the solder resist film is formed on the front surface of the conductor layer other than the electronic component mounting portion of the circuit board.

12. A power semiconductor module comprising;
an arm including two power semiconductor devices that are capable of performing switching operations and are connected in series;
a pair of positive-side and negative-side DC input terminals and output terminals that are electrically connected to the arm; and
snubber circuits connected between the DC input terminals and the output terminals respectively, wherein the pair of positive-side and negative-side DC input terminals are provided on a first side surface of the power semiconductor module and the output terminals are provided on a second side surface of the power semiconductor module on a side opposite to the first side surface, and
wherein each of the snubber circuits comprises a circuit board and an electronic component, the circuit board having an insulating base and a conductor layer, the insulating base extending along a side surface of the power semiconductor module and bridging between a corresponding one of the DC input terminals and a corresponding one of the output terminals, the conductor layer being provided on at least one of an upper surface and a lower surface of the insulating base and forming a circuit pattern connected to the corresponding DC input terminal and the corresponding output terminal respectively, and the electric component being mounted on the circuit board in an exposed manner.

13. An induction heating power supply apparatus comprising an inverter configured to convert DC power into AC power,
wherein the inverter is configured as a bridge circuit having a plurality of parallel connected power semiconductor modules according to claim 12.

14. The power semiconductor module according to claim 2, wherein the shield plate has a shield plate fixation portion configured to be fixed to the casing such that, when the shield plate fixation portion is fixed to the casing, the shield plate is grounded.

15. An induction heating power supply apparatus comprising an inverter configured to convert DC power into AC power
wherein the inverter is configured as a bridge circuit including a plurality of interconnected power semiconductor modules according to claim 2.

16. An induction heating power supply apparatus comprising an inverter configured to convert DC power into AC power
wherein the inverter is configured as a bridge circuit including a plurality of interconnected power semiconductor modules according to claim 3.

17. An induction heating power supply apparatus comprising an inverter configured to convert DC power into AC power
wherein the inverter is configured as a bridge circuit including a plurality of interconnected power semiconductor modules according to claim 4.

18. An induction heating power supply apparatus comprising an inverter configured to convert DC power into AC power
wherein the inverter is configured as a bridge circuit including a plurality of interconnected power semiconductor modules according to claim 5.

19. The snubber circuit according to claim 8, wherein a total thickness of the conductor layer is equal to or greater than 0.1 mm but smaller than 2.0 mm.

20. The snubber circuit according to claim 8, wherein the electronic component includes a soldered component, and
wherein a solder resist film is formed on a front surface of the conductor layer and in a periphery of the electronic component mounting portion of the circuit board where the soldered component is soldered.
